(19) United States
(12) Patent Application Publication
(10) Pub. No.: US 2012/0308918 A1
(43) Pub. Date: Dec. 6, 2012

(54) Photosensitive Recording Material

(76) Inventor: Emilia Mihaylova, Balbriggan Co. Dublin (IE)

(21) Appl. No.: 13/515,753

(22) PCT Filed: Dec. 17, 2010
(86) PCT No.: PCT/EP2010/070157

§ 371 Date: Aug. 3, 2012

(30) Foreign Application Priority Data
Dec. 17, 2009 (GB) 0922068.2

(51) Int. Cl. G03F 7/004

(52) U.S. Cl. 430/2

(57) ABSTRACT

The present application provides an improved photosensitive holographic recording composition. In particular, the improvement comes from adding glycerol.

### FIELD OF THE APPLICATION

The present application relates generally to the field of holography. More particularly, the present application relates to a holographic recording mediums and formulations for same. In an exemplary arrangement the present application relates to a photosensitive recording material that is useable in holographic applications.

### BACKGROUND TO THE APPLICATION

Holography is well known and widely used in many commercial applications including display holography, security, advertising and holographic optical elements and gratings. A holographic image is produced when light is diffracted at a complex spatially varying diffraction grating, which, in the simplest terms, re-directs the light towards the viewer in such a way as to give the illusion that the light is coming from a solid three-dimensional object.

This diffraction grating is produced by exposing a suitable photosensitive material to the optical interference pattern produced when two coherent light beams (usually produced by a laser) meet. The material records the variation in light intensity (as a variation in refractive index, absorption or thickness) and a corresponding diffraction grating results. If both light beams are simple collimated beams, the result will be a simple diffraction grating whose spatial period depends on the angle between the recording beams.

If the diffraction grating is illuminated with one of the recording beams (or a similar beam) it will diffract the light to reproduce the other recording beam. If one of the beams is a complex wavefront coming from a three dimensional object, the recorded diffraction grating will have the property that it can reconstruct this wavefront when illuminated with the other beam.

A wide variety of photosensitive materials are available which are suitable for recording holograms including photopolymers, silver halides, dichromated gelatin, photo resists, thermoplastics, photochromics and photorefractive materials.

Whilst the above described materials work well, it would be advantageous if the recording speed/sensitivity of the material to light and/or the diffraction efficiency of recorded holograms could be improved upon.

The present application is directed to improving the performance of photosensitive holographic recording materials and\or providing alternative formulations for holographic recording materials.

### SUMMARY

The present application provides a photosensitive holographic recording composition comprising glycerol. It has been found that the inclusion of glycerol in such compositions significantly improves their performance.

More particularly, the present application provides a composition in accordance with the claims which follow.

### DESCRIPTION OF DRAWINGS

The present application will now be described generally with respect generally to the accompanying drawing in which:

FIG. 1 is a method of improving the performance of a holographic recording composition according to an embodiment of the present application.

### DETAILED DESCRIPTION

The background to the present application is that the inventor was attempting to develop an alternative composition to that disclosed in WO 2008003661 which is assigned to the assignee of the present application. Accordingly, the present application will now be discussed in the context of the contents of this application, the content of which is incorporated herein by way of reference. However, it will be understood that the present application is not be construed as being limited to this and that the methods and additives described herein are suitable for a variety of different holographic recording materials. Moreover, it will be appreciated that any composition may be tested to determine the effectiveness of the additive of the present application improves the performance of the composition, simply by formulating the composition with and without the additive, creating a hologram in each using the same process and then comparing the results.

More particularly, WO 2008003661 discloses a photosensitive layer formed using a composition employing a number of individual components including: a dye, a free radical generator, a monomer and, optionally, a binder. WO 2008003661 details how the presence or absence of one of these components, typically the dye, may be employed as a sensing mechanism.

The role of the photosensitive dye in the photosensitive layer is to absorb light and start the photochemical processes that leads to holographic recording. Examples of photosensitive dye would include erythrosine B, fluorescein and other xanthene dyes.

In bright regions of the produced interference pattern, the energy from photons of light raises the dye molecules to excited singlet states. Many of the singlet state excited molecules are then converted to triplet state excited molecules by intersystem crossing. In the triplet state, a dye molecule can interact with a free radical generator, for example, triethanolamine. This interaction produces an active free radical. The active free radical can, in turn, interact with a monomer molecule such as acrylamide creating a monomer radical. The creation of the monomer radical, results in free radical polymerization occurring in the polymer material.

Conversion of the carbon-carbon double bond to a single bond changes the molecular polarizability of the acrylamide and thus its refractive index. In addition, the depletion of monomer concentration in illuminated regions results in a spatial gradient of monomer concentration inducing diffusion of monomer from dark to bright regions.

In greater detail, the holographic recording medium disclosed in WO 2008003661 employed acrylamide as an the monomer, with the binder being polyvinyl alcohol (PVA), a second monomer (NN′methylenebisacrylamide) was employed in the composition as a crosslinking monomer, with Triethanolamine (TEA) employed in the composition as the free radical generator and Erythrosin B employed as the dye sensitizer.

Specific monomers identified in WO 2008003661 included: acrylamides including N,N-Diethyl acrylamide, Tradename: DEAA; N,N Dimethyl acrylamide, Tradename—NNDMA; N-Isopropyl acrylamide, Tradename—NIPAM; N-(2-Hydroxyethyl acrylamide), Tradename—HEAA; or 20Hydroxyethyl methacrylate, Tradename—HEMA, or acrylate such as: N,N Dimethylaminoethyl Acrylate; or N,N Dimethylaminoethyl Methacrylate. In accordance with the present teaching, the inclusion of glycerol with any of these monomers can result in a new photopolymer with improved performance. Advantageously, there is no need for a second\cross linking monomer as the glycerol, in a way, performs the role of the cross linking monomer.

Whilst the performance of the compositions employed in W200803661 was very good, it was identified as desirable to reduce\eliminate the presence of certain acrylamides in the composition as these have a perceived health risk and accordingly might not be suitable for products being employed in a large scale commercial environment. Unfortunately, reducing the amount of acrylamides present or attempting to use alternatives resulted in compositions with inferior operating characteristics, for example, lower sensitivity to light.

Thus experiments with the use of alternative monomers such as N,N′-methylenebisacrylamide (C₇H₁₀N₂O₂), which have significantly lower toxicity proved unsatisfactory as the resulting compositions were not sufficiently photosensitive.

Accordingly, the present inventor sought to generally improve the photosensitive performance of compositions using alternative monomers having a lower toxicity. This has been achieved by the inclusion of an additive in the composition. Moreover, it has been found that the performance of the original compositions has also improved when the additive is included within the composition and accordingly the use of the additive has been found to be of general advantage in the manufacture of a photosensitive holographic recording material. More specifically, the inclusion of glycerol with any of the monomers disclosed in W200803661 can result in a new photopolymer with improved performance. Advantageously, there is no need for a second\cross linking monomer as the glycerol, in a way, performs the role of the cross linking monomer.

As discussed above the present invention has identified that the inclusion of glycerol as an additive to any of the heretofore referenced monomers provides an unexpected and surprising improvement in the performance of the holographic recording compositions. Glycerol will be appreciated by those skilled in the art as being a chemical compound also commonly called glycerin or glycerine (other names: propane-1,2,3-triol; 1,2,3-propanetriol; 1,2,3-trihydroxypropane; glyceritol; glycyl alcohol).

The molecular formula of glycerol is given by C₃H₅(OH)_{3.} It is a colorless, odorless, viscous liquid that is widely used in pharmaceutical formulations. For human consumption, glycerol is classified by the FDA among the sugar alcohols as a caloric macronutrient. Glycerol has three hydrophilic hydroxyl groups that are responsible for its solubility in water and its hydroscopic nature. Its surface tension is 64.00 mN/m at 20° C., and it has a temperature coefficient of −0.0598 mN/(m K).

Experiments have found that the quantity of glycerol required to be added per 20 ml of photopolymer material is suitably less than 3 ml. Although, the precise amount of glycerol may vary based on the particular composition and the optimum amount may be determined by experiment.

Experiments by the present inventor have indicated that it is difficult to get a layer of the photopolymer to dry if more than 5 ml of glycerol per 20 ml is added. Similarly, experiments have shown that for a reasonable increase in performance, it is necessary to employ above 0.1 ml of glycerol per 20 ml.

The quantity of dye stock solution may vary but in general it is less than for the same quantity of standard photopolymer, without glycerol.

In all photopolymer applications the speed of formation of the grating or hologram is greatly improved leading to less expensive manufacture (less laser light needed), more rapid recording (less time needed, faster throughput) and reduced stability issues (due to more rapid recording).

The improved performance allows for a number of applications which were previously impractical, including the use of holograms for commercial data storage media as its higher photosensitivity allows high speed record and read performance (high photosensitivity); short times/low energies required to utilize 80% of the dynamic range; short manufacturing cycle time; good optical clarity and low level of light scatter with high responsivity of the media to the write process.

Colour holography applications—fast recording; bigger size brighter colour holograms with the same laser intensity; no over modulation.

Accordingly, the present application provides a new low toxicity composition comprising:
a monomer (an acrylamide), suitably N,N′-methylenebisacrylamide or N-(1,1-DIMETHYL-3-OXOBUTYL)-ACRYLAMIDE;
an emulsifier, for example, Triethanolaamine (TEA);
a dye (for example Methylene Blue), glycerol and optionally a polymer, for example Polyvinyl Alcohol (PVA);
   The amounts of each will now be described with reference to an exemplary formulation in which the binder is PVA and amounts to 10 ml. The monomer is N,N′-methylenebisacrylamide and the amount is in the range 0.05 g to 0.5 g. Suitably the emulsifier is TEA and the amount is in the range from 0.01 ml to 2 ml. Suitably, the dye comprises 0.01 ml to 5 ml of a Methylene Blue stock solution (the stock solution in turn suitably comprises about 0.055 g Methylene Blue powder dye dissolved in 50 ml H₂O). Additionally experimentation with N-(1,1-DIMETHYL-3-OXOBUTYL)-ACRYLAMIDE sold under the trade name DIACETONE ACRYLAMIDE (DAAM) from Kyowa Hakko Chemical Co., Ltd. has provided good results.

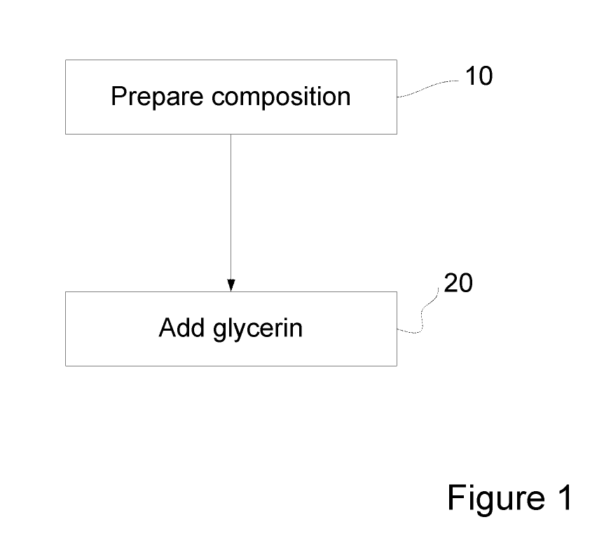

The process, as shown in FIG. 1, of preparing the formulation comprises the step of mixing 10 the PVA, the monomer (N,N′-methylenebisacrylamide), TEA and dye stock solution together. The glycerol may be added 20 at the same time or after the initial formulation has been mixed.

Optimum results have been achieved where the glycerol was pre-mixed with the dye stock solution in advance and subsequently added to the mixture of PVA, the monomer and TEA. It has been observed that by including the use of glycerol, there is no need for an additional cross linking monomer.

Although, the present application has been described with reference to a particular holographic compositions, it will be appreciated than the use of glycerol as an additive is not intended to be limited to these particular compositions and may be employed within other photosensitive compositions, methods and products, for example of the types disclosed in, U.S. Pat. No. 7,214,451, U.S. Pat. No. 7,332,249, U.S. Pat. No. 7,070,886, U.S. Pat. No. 7,297,448, U.S. Pat. No. 6,784,300, U.S. Pat. No. 7,521,154, U.S. Pat. No. 6,939,648, U.S. Pat. No. 7,483,189, U.S. Pat. No. 6,743,552, U.S. Pat. No. 6765061, U.S. Pat. No. 6,780,546, U.S. Pat. No. 6,482,551, U.S. Pat. No. 7,229,741, EP0374875, U.S. Pat. No. 4,996,120, U.S. Pat. No. 5,013,632, U.S. Pat. No. 5,238,777, U.S. Pat. No. 5,264,329, U.S. Pat. No. 5,710,193, U.S. Pat. No. 3,658,526, the entire contents of each of which is hereby incorporated by reference in the context of including glycerol as an additive to the compositions described therein.

It will also be appreciated that whilst the present application has been discussed with respect to glycerol, it will be appreciated that a glycerol based derivatives may also be employed and are accordingly intended to come within the scope of the present application.

1. A photosensitive holographic recording composition characterized in that the composition is a water-soluble photopolymer comprising an acrylamide monomer and the composition further comprises glycerol or a glycerol derivative.

2. A photosensitive holographic recording composition, wherein the monomer is N,N′-methylenebisacrylamide or N-(1,1-dimethyl-3-oxobutyl)-acrylamide.

3. A composition according to claim 1, wherein the amount of glycerol is less than 5 ml per 20 ml of composition.

4. A composition according to claim 1, wherein the amount of glycerol is greater than 0.1 ml and 3 ml per 20 ml of composition.

5. A composition according to claim 1, further comprising a polymer.

6. A composition according to claim 5, wherein the polymer is polyvinyl alcohol or a mixture of polyvinyl alcohol and polyvinylpyrrolidone.

7. A composition according to claim 1, wherein the amount of monomer is in the range of 0.05 g to 1 g per 20 ml of composition.

8. A composition according to claim 7, wherein the amount of the monomer is between 0.1 g to 0.8 g per 20 ml of composition.

9. A composition according to claim 7, wherein the amount of monomer is between 0.55 g and 0.65 g per 20 ml of composition.

10. A composition according to claim 7, wherein the amount of the monomer is about 0.6 g per 20 ml of composition.

11. A composition according to claim 1 further comprising a dye.

12. A composition according to claim 11, wherein the dye comprises Methylene Blue.

13. A method of improving the photosensitive performance of a holographic recording material composition comprising an acrylamide monomer, comprising the step of adding glycerol or a glycerol derivative to the composition.

14. A method according to claim 13, wherein the volume of glycerol once added is less than 5 ml per 20 ml of the composition.

15. A method according to claim 14, wherein the volume of glycerol once added is between 0.1 ml and 3 ml per 20 ml of the composition.
